(19) United States
(12) Patent Application Publication
(10) Pub. No.: US 2024/0201603 A1
(43) Pub. Date: Jun. 20, 2024

(54) AIR COOLING APPARATUS, ENVIRONMENTAL CONTROL APPARATUS, LITHOGRAPHY APPARATUS, AND ARTICLE MANUFACTURING METHOD

(71) Applicant: CANON KABUSHIKI KAISHA, Tokyo (JP)

(72) Inventor: SHINTARO AICHI, Tochigi (JP)

(21) Appl. No.: 18/533,586

(22) Filed: Dec. 8, 2023

(30) Foreign Application Priority Data
Dec. 14, 2022 (JP) 2022-199551

(51) Int. Cl. G03F 7/00; F25B 39/00; F28D 15/02

(52) U.S. Cl. CPC G03F 7/70858; F25B 39/00; F28D 15/02

(57) ABSTRACT

An air cooling apparatus for cooling air, includes a container, a boiling section arranged in the container, and a condensing section arranged in the container and above the boiling section. The boiling section includes a separator configured to separate a first path through which air of a cooling target moves and a second path through which a refrigerant moves. The separator includes a first heat exchanger configured to cause the air and the refrigerant to exchange heat. The refrigerant boiled in the second path by cooling the air is condensed in the condensing section.

### BACKGROUND OF THE INVENTION

### Field of the Invention

The present invention relates to an air cooling apparatus, an environmental control apparatus, a lithography apparatus, and an article manufacturing method.

### Description of the Related Art

Japanese Patent Laid-Open No. 2000-283500 describes a cooling apparatus including a freezer including a compressor and a condenser, and a heat exchanger that cools air-conditioning air by a refrigerant cooled by the freezer. Japanese Patent Laid-Open No. 2000-283500 also describes an additional heat exchanger that cools a secondary refrigerant by a primary refrigerant that is the refrigerant of the freezer, and a secondary refrigerant circulation circuit that supplies the secondary refrigerant to the heat exchanger that cools the air-conditioning air. A configuration using a freezer, like Japanese Patent Laid-Open No. 2000-283500, is disadvantageous in size reduction of a cooling apparatus.

### SUMMARY OF THE INVENTION

The present invention provides an air cooling apparatus having a configuration advantageous in size reduction.

One of aspects of the present invention is related to an air cooling apparatus for cooling air, and the apparatus comprises: a container; a boiling section arranged in the container; and a condensing section arranged in the container and above the boiling section, wherein the boiling section includes a separator configured to separate a first path through which air of a cooling target moves and a second path through which a refrigerant moves, the separator including a first heat exchanger configured to cause the air and the refrigerant to exchange heat, and the refrigerant boiled in the second path by cooling the air is condensed in the condensing section.

Further features of the present invention will become apparent from the following description of exemplary embodiments with reference to the attached drawings.

### BRIEF DESCRIPTION OF THE DRAWINGS

FIG. 1 is a view schematically showing the configuration of an environmental control apparatus according to the first embodiment;

FIG. 2 is a view schematically showing the configuration of an air cooling apparatus in the environmental control apparatus according to the first embodiment;

FIG. 3 is a view schematically showing the configuration of the air cooling apparatus in the environmental control apparatus according to the first embodiment;

FIG. 4 is a view schematically showing the configuration of the air cooling apparatus in the environmental control apparatus according to the first embodiment;

FIG. 5 is a view exemplarily showing a structure formed by a plurality of first heat exchange plates and a plurality of tubes;

FIG. 6 is a view exemplarily showing a structure formed by a plurality of first heat exchange plates and a plurality of tubes;

FIG. 7 is a view showing an example of the configuration of a guide;

FIG. 8 is a view schematically showing the configuration of an environmental control apparatus according to the second embodiment; and

FIG. 9 is a view schematically showing the configuration of a lithography apparatus according to an embodiment.

### DESCRIPTION OF THE EMBODIMENTS

Hereinafter, embodiments will be described in detail with reference to the attached drawings. Note, the following embodiments are not intended to limit the scope of the claimed invention, and limitation is not made to an invention that requires a combination of all features described in the embodiments. Two or more of the multiple features described in the embodiments may be combined as appropriate. Furthermore, the same reference numerals are given to the same or similar configurations, and redundant description thereof is omitted.

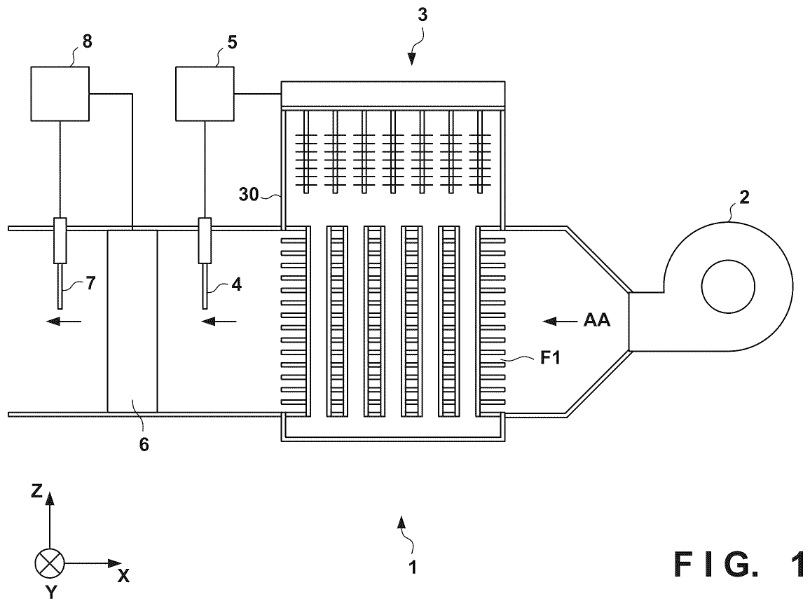

In this specification and attached drawings, directions will be explained in accordance with an XYZ coordinate system. FIG. 1 schematically shows the configuration of an environmental control apparatus 1 according to the first embodiment. The environmental control apparatus 1 can include, for example, a blower 2, an air cooling apparatus 3, and an air heater 6. The blower 2 forms the flow of air AA such that the air AA is cooled by the air cooling apparatus 3 and then heated by the air heater 6. The blower 2 may be arranged on the upstream side of the air cooling apparatus 3, as exemplified in FIG. 1, or may be arranged on the downstream side of the air heater 6. In a case where the environmental control apparatus 1 is connected to a chamber that defines a space as the target of environmental control, the environmental control apparatus 1 is configured to receive air from the chamber via the first port of the chamber and supply air to the chamber via the second port of the chamber.

The environmental control apparatus 1 can include a temperature sensor 4 that detects the temperature of the air AA coming out of the air cooling apparatus 3, and a controller 5 that controls the air cooling apparatus 3 based on the output of the temperature sensor 4 such that the temperature of the air AA coming out of the air cooling apparatus 3 matches a target cooling temperature. The temperature sensor 4 can be arranged between the air cooling apparatus 3 and the air heater 6. The environmental control apparatus 1 can include a temperature sensor 7 that detects the temperature of the air AA coming out of the air heater 6, and a controller 8 that controls the air heater 6 based on the output of the temperature sensor 7 such that the temperature of the air AA coming out of the air heater 6 matches a target temperature. The controller 5 and the controller 8 can be formed by, for example, a Programmable Logic Device (PLD) such as a Field Programmable Gate Array (FPGA) an Application Specific Integrated Circuit (ASIC), a general-purpose or dedicated computer in which a program is installed, or a combination of some or all of these. The controller 5 and the controller 8 may be formed as one controller. A chemical filter may be arranged between the air cooling apparatus 3 and the air heater 6.

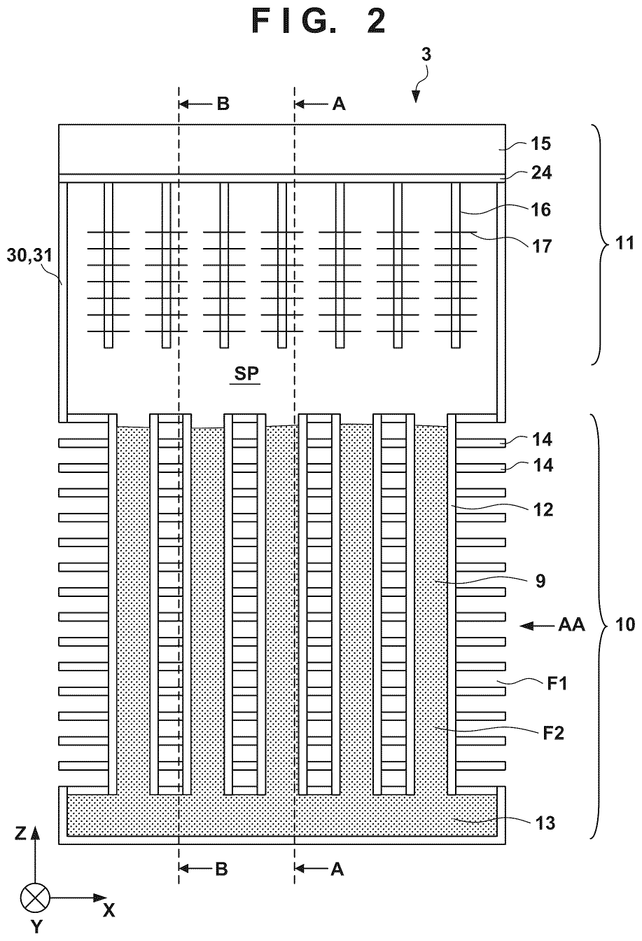

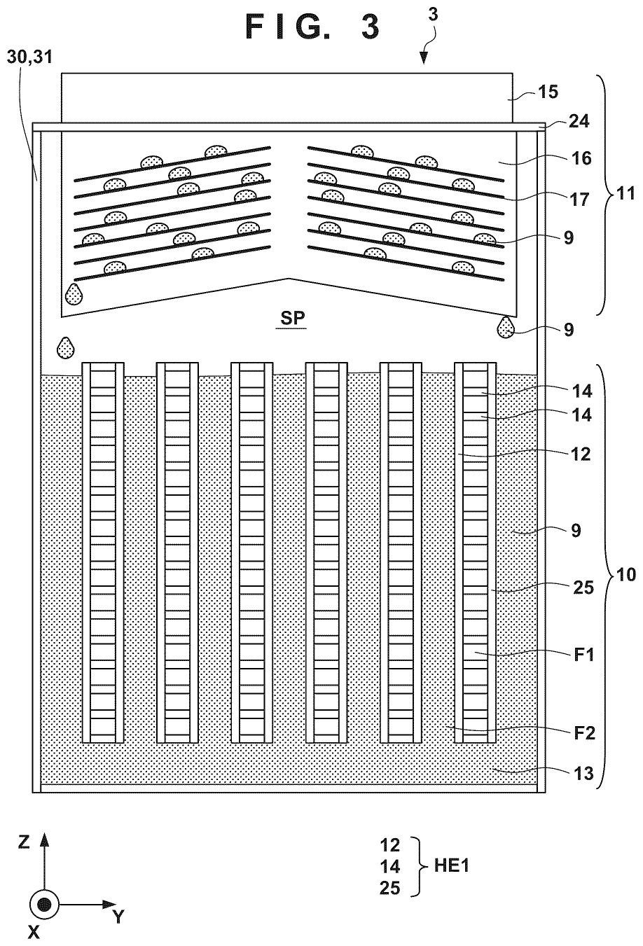

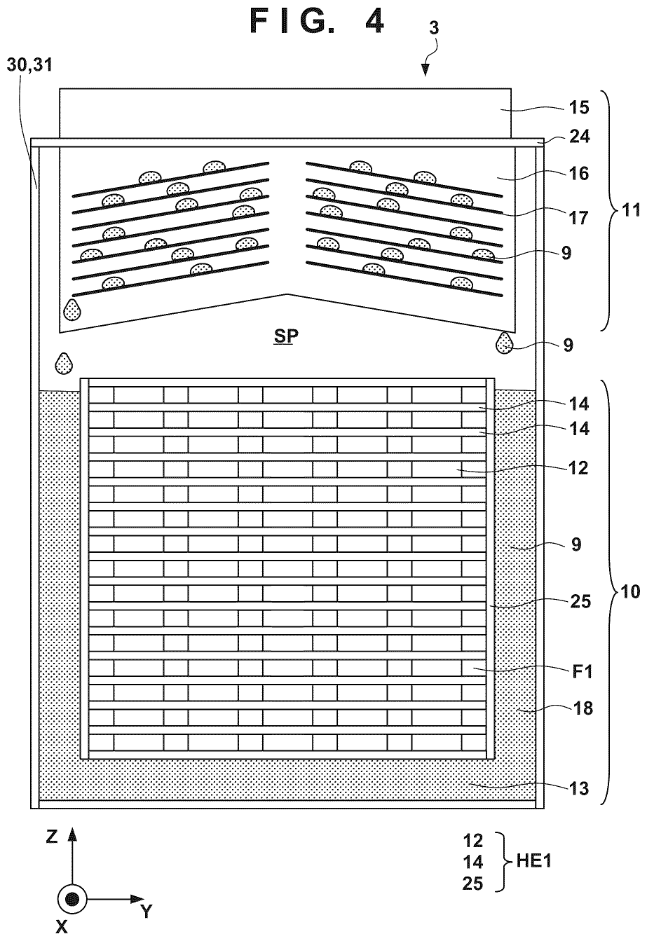

FIGS. 2, 3, and 4 schematically show the configuration of the air cooling apparatus 3. The flow of the air AA formed by the blower 2 is directed from right to left in FIG. 2. FIG. 3 is a sectional view taken along a line A-A in FIG. 2, and FIG. 4 is a sectional view taken along a line B-B in FIG. 2. The air cooling apparatus 3 that cools the air AA can include a container 30, a boiling section 10 arranged in the container 30, and a condensing section 11 arranged in the container 30 and above the boiling section 10. The boiling section 10 can include a separator that separates a first path F1 through which the air AA of the cooling target moves and a second path F2 through which a refrigerant 9 moves. The separator can include a first heat exchanger HE1 that causes the air AA moving in the first path F1 and the refrigerant 9 moving in the second path F2 to exchange heat. The refrigerant 9 boiled in the second path F2 by cooling the air AA can be condensed in the condensing section 11.

The container 30 can be configured to support the boiling section 10 and the condensing section 11. The condensing section 11 can be arranged to face the boiling section 10 via a space SP in the container 30. The air cooling apparatus 3 can be configured such that the refrigerant 9 boiled in the second path F2 of the boiling section 10 reaches the condensing section 11 via the space SP. When the refrigerant 9 is boiled in the second path F2, the air AA moving in the first path F1 is cooled via the first heat exchanger HE1. In other words, heat of the air AA moving in the first path F1 is transmitted to the refrigerant 9 moving in the second path F2 via the first heat exchanger HE1, and the refrigerant 9 is thus boiled.

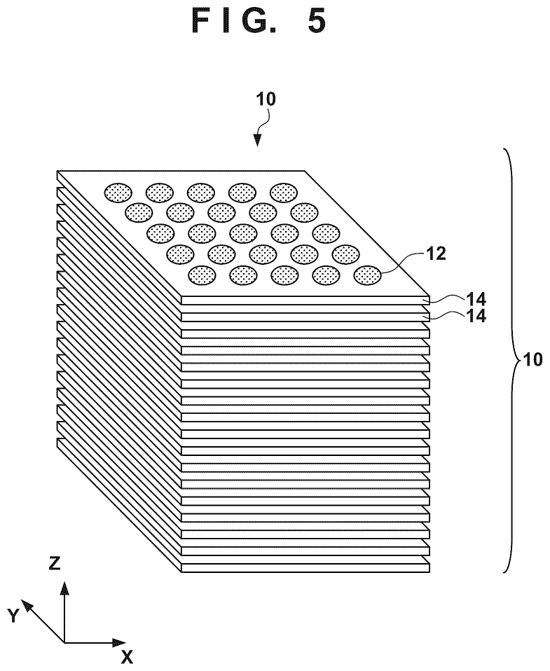

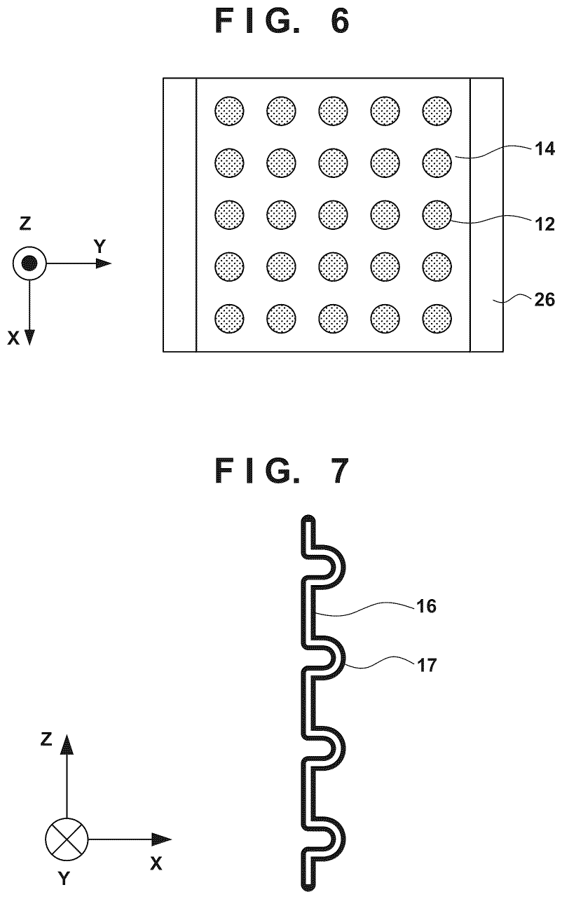

The first heat exchanger HE1 can include a plurality of first heat exchange plates 14 arranged apart from each other in the vertical direction, and a plurality of tubes 12 extending through the plurality of first heat exchange plates 14. At least a part of the first path F1 can be defined by the outer surfaces of the plurality of tubes 12, and the plurality of first heat exchange plates 14. At least a part of the second path F2 can be defined by the inner surfaces of the plurality of tubes 12. FIGS. 5 and 6 schematically show a structure formed by the plurality of first heat exchange plates 14 and the plurality of tubes 12. Under the plurality of first heat exchange plates 14, the plurality of tubes 12 communicate via a communicating section 13. The first heat exchanger HE1 can further include a separation member 25 arranged on sides of the plurality of first heat exchange plates 14 to separate the first path F1 and the second path F2. Note that the separation member 25 is not illustrated in FIG. 5. In the internal space of the container 30, the boiling point of the refrigerant 9 is lower than the temperature of the air AA of the cooling target supplied to the boiling section 10. For example, the boiling point of the refrigerant 9 under the atmospheric pressure is lower than 25° C., 24° C., 23° C., 22° C., 21° C., 20° C., 19° C., 18° C., 17° C., 16° C., or 15° C.

As exemplified in FIGS. 3 and 4, the condensing section 11 can include a guide 17 that guides the condensed refrigerant 9 to a circulation path 18 between the separation member 25 and the wall member 31 that forms a part of the container 30. The condensed refrigerant 9 is, for example, guided by the guide 17 and then dropped to the circulation path 18 by gravity acting on the refrigerant 9.

The refrigerant 9 boiled in the boiling section 10, that is, the vaporized refrigerant 9 can be condensed, that is, liquified in the condensing section 11 arranged above the boiling section 10 and guided to the guide 17. The condensing section 11 can include a plurality of second heat exchange plates 16 that condense the boiled refrigerant 9. The boiled or vaporized refrigerant 9 can be condensed when its heat is taken by the plurality of second heat exchange plates 16.

The condensing section 11 can further include a temperature regulator 15 that adjusts the temperature of the plurality of second heat exchange plates 16. The temperature regulator 15 or the condensing section 11 can be controlled by the controller 5 based on the output of the temperature sensor 4 such that the temperature of the air AA coming out of the air cooling apparatus 3 matches the target cooling temperature. The plurality of second heat exchange plates 16 can be arranged apart from each other in the horizontal direction. The plurality of second heat exchange plates 16 can be supported by, for example, a support plate (support member) 24. The plurality of second heat exchange plates 16 can be connected to the temperature regulator 15 via, for example, the support plate (support member) 24. The guide 17 can have liquid repellency to the refrigerant 9. The guide 17 can be provided on at least one of the plurality of second heat exchange plates 16.

The temperature regulator 15 can include, for example, a Peltier element. The heat dissipation section of the Peltier element can be cooled by a gas such as air or a liquid such as water. Since the temperature of the heat dissipation section of the Peltier element is high, the heat can be dissipated using facility cooling water. Hence, the air cooling apparatus 3 or the temperature regulator 15 does not need a freezer. This can contribute to size reduction and simplification of the air cooling apparatus 3 or the environmental control apparatus 1.

The controller 5 can maintain boiling and condensation of the refrigerant 9 in the internal space of the container 30 in equilibrium based on the output of the temperature sensor 4 that detects the temperature of the air AA coming out of the air cooling apparatus 3 via the first path F1. Maintaining the refrigerant 9 in equilibrium makes it possible to suppress rise of the temperature of the refrigerant 9 beyond its boiling point. This is advantageous in evenly maintaining the temperature of air provided from the air cooling apparatus 3 or the environmental control apparatus 1.

The surfaces of the plurality of second heat exchange plates 16 and the plurality of guides 17 preferably have liquid repellency to the refrigerant 9. The liquid repellency improves the speed of the refrigerant 9 moving along the plurality of second heat exchange plates 16 and the plurality of guides 17 and is therefore advantageous in increasing the condensation efficiency.

In the plurality of tubes 12, the refrigerant 9 preferably causes nucleate boiling. This is because in film boiling, boiling occurs via a vapor film covering a heat transfer surface, and therefore, the thermal resistance becomes high, and efficiency lowers. To cause nucleate boiling, it is preferable that, to cause boiling using a cavity in the heat transfer surface as a nucleus, the inner surface of the tube 12 is made rough or a porous body is arranged in the tube 12. These have an effect of promoting generation of bubbles. To improve the heat exchange efficiency, the tubes 12, the first heat exchange plates 14, the second heat exchange plates 16, and the guides 17 are preferably made of copper or aluminum with excellent thermal conductivity.

As schematically shown in FIG. 7, the guides 17 may be formed by embossing at least one of the plurality of second heat exchange plates 16 or preferably each of the plurality of second heat exchange plates 16.

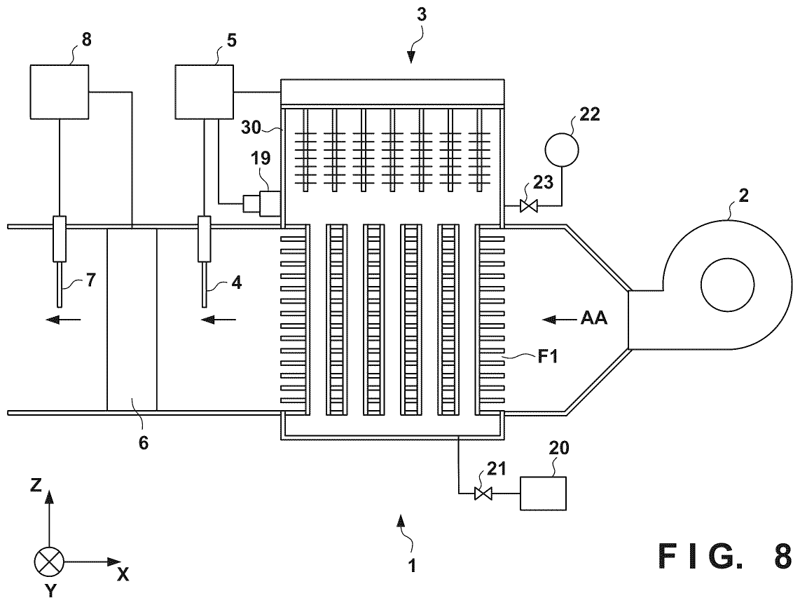

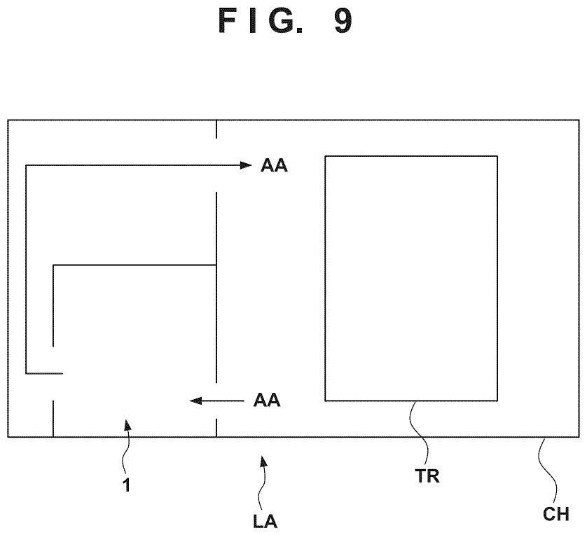

FIG. 8 schematically shows the configuration of an environmental control apparatus 1 according to the second embodiment. Matters that are not mentioned below as the second embodiment can comply with the first embodiment. In the second embodiment, the environmental control apparatus 1 or an air cooling apparatus 3 can include a pump 22 that exhausts a gas in a container 30. The environmental control apparatus 1 or the air cooling apparatus 3 may further include a valve 23 between the container 30 and the pump 22. The valve 23 can be controlled by a controller 5. The environmental control apparatus 1 or the air cooling apparatus 3 may further include a supply section 20 that supplies a refrigerant 9 into the container 30. The environmental control apparatus 1 or the air cooling apparatus 3 may further include a valve 21 between the container 30 and the supply section 20. The valve 21 can be controlled by the controller 5. The environmental control apparatus 1 or the air cooling apparatus 3 may further include a pressure sensor 19 that detects the pressure in the container 30. The controller 5 can control one or both of the valve 23 and the valve 21 based on the output of the pressure sensor 19.

The controller 5 can monitor the state of the internal space of the container 30 of the air cooling apparatus 3 based on the output of the pressure sensor 19. If a leakage occurs in the container 30, air may enter the internal space of the container 30. If air enters the internal space of the container 30, the partial pressure changes, and the pressure at which the refrigerant 9 is boiled (the pressure in the equilibrium state) changes. Based on the change of the pressure at which the refrigerant 9 is boiled, a controller 8 can detect occurrence of an abnormality in the air cooling apparatus 3. If the leakage amount is permissible, the controller 5 can continue the operation of the air cooling apparatus 3 by controlling one or both of the valve 23 and the valve 21 based on the output of the pressure sensor 19.

FIG. 9 schematically shows the configuration of a lithography apparatus LA according to an embodiment. The lithography apparatus LA can include a chamber CH, a transfer device TR that is arranged in the internal space of the chamber CH and transfers a pattern to a substrate, and an environmental control apparatus 1 arranged to adjust the temperature of the internal space of the chamber CH. The lithography apparatus LA can be, for example, an exposure apparatus or an imprint apparatus. The exposure apparatus can be configured to project the pattern of an original to a substrate via a projection optical system, thereby transferring the pattern of the original to (a photoresist film on) a substrate. The imprint apparatus can be configured to bring an original (mold) into contact with an imprint material on a substrate and then cure the imprint material, thereby transferring the pattern of the original to (the imprint material on) the substrate.

The above-described lithography apparatus LA can be used in an article manufacturing method. The article manufacturing method can include a pattern formation step of forming a pattern on a substrate using the lithography apparatus LA, and a processing step of processing the substrate with the pattern formed thereon, thereby obtaining an article. For example, if the lithography apparatus LA is an exposure apparatus, the processing step can include at least one of a development step, an etching step, and an ion implantation step. For example, if the lithography apparatus LA is an imprint apparatus, the processing step can include at least one of an etching step and an ion implantation step.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-199551, filed Dec. 14, 2022, which is hereby incorporated by reference herein in its entirety.

What is claimed is:

1. An air cooling apparatus for cooling air, comprising:
a container;
a boiling section arranged in the container; and
a condensing section arranged in the container and above the boiling section,
wherein the boiling section includes a separator configured to separate a first path through which air of a cooling target moves and a second path through which a refrigerant moves, the separator including a first heat exchanger configured to cause the air and the refrigerant to exchange heat, and
the refrigerant boiled in the second path by cooling the air is condensed in the condensing section.

2. The apparatus according to claim 1, wherein the container supports the boiling section and the condensing section.

3. The apparatus according to claim 2, wherein the condensing section faces the boiling section via a space in the container.

4. The apparatus according to claim 3, wherein the refrigerant boiled in the second path of the boiling section reaches the condensing section via the space.

5. The apparatus according to claim 1, wherein
the first heat exchanger includes a plurality of first heat exchange plates arranged apart from each other in a vertical direction, and a plurality of tubes extending through the plurality of first heat exchange plates,
at least a part of the first path is defined by outer surfaces of the plurality of tubes, and the plurality of first heat exchange plates, and
at least a part of the second path is defined by inner surfaces of the plurality of tubes.

6. The apparatus according to claim 5, wherein the plurality of tubes communicate under the plurality of first heat exchange plates.

7. The apparatus according to claim 6, wherein the first heat exchanger further includes a separation member arranged on sides of the plurality of first heat exchange plates to separate the first path and the second path.

8. The apparatus according to claim 7, wherein the condensing section includes a guide configured to guide the condensed refrigerant to a space between the separation member and a wall member that forms a part of the container.

9. The apparatus according to claim 8, wherein the condensing section further includes a plurality of second heat exchange plates configured to condense the boiled refrigerant.

10. The apparatus according to claim 9, wherein the plurality of second heat exchange plates are arranged apart from each other in a horizontal direction.

11. The apparatus according to claim 8, wherein the guide has liquid repellency to the refrigerant.

12. The apparatus according to claim 11, wherein the guide is provided on at least one of the plurality of second heat exchange plates.

13. The apparatus according to claim 10, wherein the guide is formed by embossing at least one of the plurality of second heat exchange plates.

14. The apparatus according to claim 10, further comprising:
a temperature regulator configured to adjust a temperature of the plurality of second heat exchange plates;
a temperature sensor configured to detect a temperature of the air that has passed through the first path; and
a controller configured to control the temperature regulator based on an output of the temperature sensor.

15. The apparatus according to claim 1, wherein a boiling point of the refrigerant is lower than a temperature of the air of the cooling target supplied to the boiling section.

16. The apparatus according to claim 1, further comprising a pump configured to exhaust a gas in the container.

17. The apparatus according to claim 1, further comprising a supply section configured to supply a refrigerant into the container.

18. The apparatus according to claim 1, further comprising a pressure sensor configured to detect a pressure in the container.

19. An environmental control apparatus comprising:
an air cooling apparatus configured to cool air, and including a container, a boiling section arranged in the container, and a condensing section arranged in the container and above the boiling section, wherein the boiling section includes a separator configured to separate a first path through which air of a cooling target moves and a second path through which a refrigerant moves, the separator including a first heat exchanger configured to cause the air and the refrigerant to exchange heat, and wherein the refrigerant boiled in the second path by cooling the air is condensed in the condensing section; and
an air heater configured to heat air cooled by the air cooling apparatus.

20. A lithography apparatus comprising:
a chamber;
a transfer device arranged in an internal space of the chamber and configured to transfer a pattern to a substrate; and
an environmental control apparatus arranged to adjust a temperature of the internal space of the chamber,
wherein the environmental control apparatus comprises:
an air cooling apparatus configured to cool air, and including a container, a boiling section arranged in the container, and a condensing section arranged in the container and above the boiling section, wherein the boiling section includes a separator configured to separate a first path through which air of a cooling target moves and a second path through which a refrigerant moves, the separator including a first heat exchanger configured to cause the air and the refrigerant to exchange heat, and wherein the refrigerant boiled in the second path by cooling the air is condensed in the condensing section; and
an air heater configured to heat air cooled by the air cooling apparatus.

21. An article manufacturing method comprising:
forming a pattern on a substrate using a lithography apparatus defined in claim 20; and
processing the substrate with the pattern formed thereon, thereby obtaining an article.
